(19) United States
(12) Patent Application Publication
(10) Pub. No.: US 2012/0125764 A1
(43) Pub. Date: May 24, 2012

(54) METHOD FOR PRODUCING OXIDE THIN FILM

(75) Inventor: Hiroyuki FUKUSHIMA, Tokyo (JP)

(73) Assignee: FURUKAWA ELECTRIC CO., LTD., Tokyo (JP)

(21) Appl. No.: 13/296,786

(22) Filed: Nov. 15, 2011

(30) Foreign Application Priority Data
Nov. 17, 2010 (JP) 2010-257246

(51) Int. Cl. C23C 14/46; C23C 14/08; C23C 14/35

(52) U.S. Cl. 204/192.11

(57) ABSTRACT

A method for producing an oxide thin film, including depositing sputtered particles from a metallic deposition source on a deposition area under the condition of a sputtering energy density of 9.5 W/cm² to 20 W/cm² according to a magnetron sputtering method to form the oxide thin film, while irradiating an ion beam from an oblique direction with respect to the deposition area.

### CROSS-REFERENCE TO RELATED APPLICATION

This application claims priority under 35 USC 119 from Japanese Patent Application No. 2010-257246, the disclosure of which is incorporated by reference herein.

### BACKGROUND OF THE INVENTION

1. Field of the Invention

The present invention relates to a method for producing an oxide thin film suitable as an intermediate layer or the like in high temperature superconducting wire rods used in superconducting devices such as a superconducting cable and a superconducting magnet and high magnetic field generators for NMR (nuclear magnetic resonance), nuclear fusion, accelerators, linear motors and the like.

2. Description of the Related Art

Until now, many attempts have been proposed to produce a superconducting wire rod by depositing a superconductor on a substrate.

Energization characteristics of a high temperature superconducting wire rod are known to significantly depend on crystallographic orientation of the superconductor, particularly on biaxial orientation thereof. To obtain a superconducting layer having high biaxial orientation, crystallinity of an intermediate layer as a base needs to be improved. One method for that is to perform deposition while irradiating assisting ions from an oblique direction during the deposition of an intermediate layer (IBAD method: Ion Beam-Assisted Deposition Method). From the viewpoint of obtaining a thin film with excellent biaxial orientation, a rock-salt type MgO as a target of deposition is often used, and use of the rock-salt type MgO is becoming a main stream of development. Improvement in film properties of an MgO layer formed by the IBAD method is effective to obtain excellent biaxial orientation film. For achievement of such improved film properties, apparatuses equipped with two large ion guns are often used.

As the IBAD method, there is disclosed a method in which when constituent particles knocked away from a target by sputtering are deposited on a substrate, they are deposited while simultaneously being irradiated with an ion beam generated from an ion gun from an oblique direction (for example, see JP-A-1992-331795).

Further, there is disclosed a method of depositing a film on a substrate by a deposition flux having an oblique incident angle of approximately 5° to 80° from a substrate normal line and simultaneously irradiating an ion beam at an ion beam incident angle arranged along a best or second-best ion orientation direction of the deposited film thereby forming a biaxial orientation film, and there is also disclosed a superconducting article including a superconducting layer deposited on the biaxial orientation film (for example, see JP-A-2007-532775).

### SUMMARY OF THE INVENTION

According to a first aspect of the present invention, there is provided a method for producing an oxide thin film, including depositing sputtered particles from a metallic deposition source on a deposition area under the condition of a sputtering energy density of 9.5 W/cm² to 20 W/cm² according to a magnetron sputtering method to form the oxide thin film, while irradiating an ion beam from an oblique direction with respect to the deposition area.

### BRIEF DESCRIPTION OF THE DRAWINGS

FIG. 1 is a skeleton framework showing a sputtering apparatus used in an oxide thin film production method by an IBAD method according to an embodiment of the present invention.

FIG. 2 is a skeleton framework of the sputtering apparatus shown in FIG. 1, as viewed from a substrate-conveying direction.

FIG. 3 is a view showing a laminate structure of a superconducting wire rod.

FIG. 4 is a cross-sectional detail view of the laminate structure of the superconducting wire rod shown in FIG. 3.

### DETAILED DESCRIPTION OF THE INVENTION

In a method for producing an oxide thin film according to the present invention, the oxide thin film is formed by depositing sputtered particles from a metallic deposition source on a deposition area under the condition of a sputtering energy density of 9.5 W/cm² to 20 W/cm² according to a magnetron sputtering method while irradiating an ion beam from an oblique direction with respect to the deposition area.

—Sputtering Energy Density—

In the magnetron sputtering method, RF (Radio Frequency) plasma or DC (Direct Current) plasma generates inert gas ions (for example, Ar⁺), and then by bombarding a deposition source (target) with the inert gas ions, deposition particles are sputtered from the deposition source. Herein, the “sputtering energy density” refers to a value obtained by dividing a quantity of electricity supplied to the sputtering apparatus to generate the plasma (such as RF plasma or DC plasma) by an area of a surface of the deposition source (target) with which the ions collide (the quantity of electricity/the area of the deposition source).

When the sputtering energy density is below 9.5 W/cm², a sufficient deposition rate cannot be obtained, resulting in the formation of an oxide thin film exhibiting poor biaxial orientation. Meanwhile, when the density exceeds 20 W/cm², the sputtering rate from the deposition source (target) is saturated. Thus, even if the energy density is set to be higher than that, biaxial orientation cannot be improved.

Satisfying the requirement of the sputtering energy density allows for the formation of a film having high biaxial orientation even when an oxide thin film is produced by a magnetron sputtering method using an inexpensive magnetron sputter gun instead of an expensive large ion gun as a device for sputtering deposition particles from the deposition source. Further, the assembly cost of a deposition apparatus can be reduced.

In addition, when the oxide thin film production method is used to form an intermediate layer of a superconducting wire rod, enhanced characteristic features of the superconducting wire rod can be realized.

From a viewpoint of obtaining a sufficient deposition rate to achieve high biaxial orientation, the sputtering energy density is more preferably from 12 W/cm² to 16 W/cm².

The sputtering energy density is controlled by adjusting the quantity of electricity supplied to the sputtering apparatus to generate the plasma (such as RF plasma, DC plasma or the like) and also by adjusting the area of the deposition source (target).

—Distance Between Deposition Source and the Deposition Area—

Additionally, in the oxide thin film production method according to the present invention, a distance between the deposition source and the deposition area (a Target-to-Substrate (T-S) distance) is preferably from 80 mm to 100 mm.

The deposition source can be housed in a deposition source cover enclosing the source. Even in this case, the T-S distance refers to a distance between the deposition source housed in the deposition source cover and the deposition area.

By setting the T-S distance to 80 mm or more, the deposition area can be efficiently irradiated with an ion beam from an oblique direction to obtain high biaxial orientation. Meanwhile, when the distance is 100 mm or less, a high deposition rate can be obtained, resulting in obtaining of high biaxial orientation.

From the viewpoint of obtaining a sufficient deposition rate to achieve high biaxial orientation, the T-S distance is more preferably from 88 mm to 94 mm.

—Pressure of Atmospheric Gas—

Additionally, in the oxide thin film production method according to the present invention, a pressure of an atmospheric gas for carrying out sputtering by the magnetron sputtering method is preferably from 50 mPa to 700 mPa.

In the magnetron sputtering method, inert gas ions (such as Ar⁺) are generated by RF plasma or DC plasma and then collided with the deposition source (target) to sputter deposition particles from the deposition source. The sputtered deposition particles are deposited on the deposition area to form an oxide thin film. Herein, the atmospheric gas means a gas with which an environment including the deposition source and the deposition area is filled. Usually, since a sputtering apparatus for carrying out sputtering is enclosed in a case, the atmospheric gas refers to a gas with which the case is filled. In addition, when two or more kinds of atmospheric gases are used, the pressure of the atmospheric gas refers to a total pressure of those gases.

When the pressure of the atmospheric gas is 50 mPa or larger, plasma can be efficiently generated by the magnetron sputtering method. Meanwhile, when the pressure thereof is 700 mPa or smaller, the ion beams irradiated to the deposition area from the oblique direction can be efficiently stabilized.

From the viewpoint of generating plasma more efficiently and irradiating more stabilized ion beam, the pressure of the atmospheric gas is more preferably from 90 mPa to 150 mPa.

The pressure of the atmospheric gas is controlled by adjusting the kind and quantity of the gas.

The pressure of the atmospheric gas can be measured by a quadrupole mass spectrometer.

By satisfying the requirements such as the T-S distance and the pressure of the atmospheric gas, a film having higher biaxial orientation can be formed even when an oxide thin film is produced by the magnetron sputtering method using an inexpensive magnetron sputter gun instead of an expensive large ion gun as a method for sputtering deposition particles from the deposition source, and also the assembly cost of a deposition apparatus can be reduced.

Additionally, when the oxide thin film production method is used to form an intermediate layer of a superconducting wire rod, enforcement of superconductive characteristics of the superconducting wire rod can be realized.

Hereinafter, the following is a description of the sputtering method (IBAD method) for forming an oxide thin film by depositing deposition particles from a metallic deposition source on a deposition area by the magnetron sputtering method while irradiating with an ion beam from an oblique direction to the deposition area.

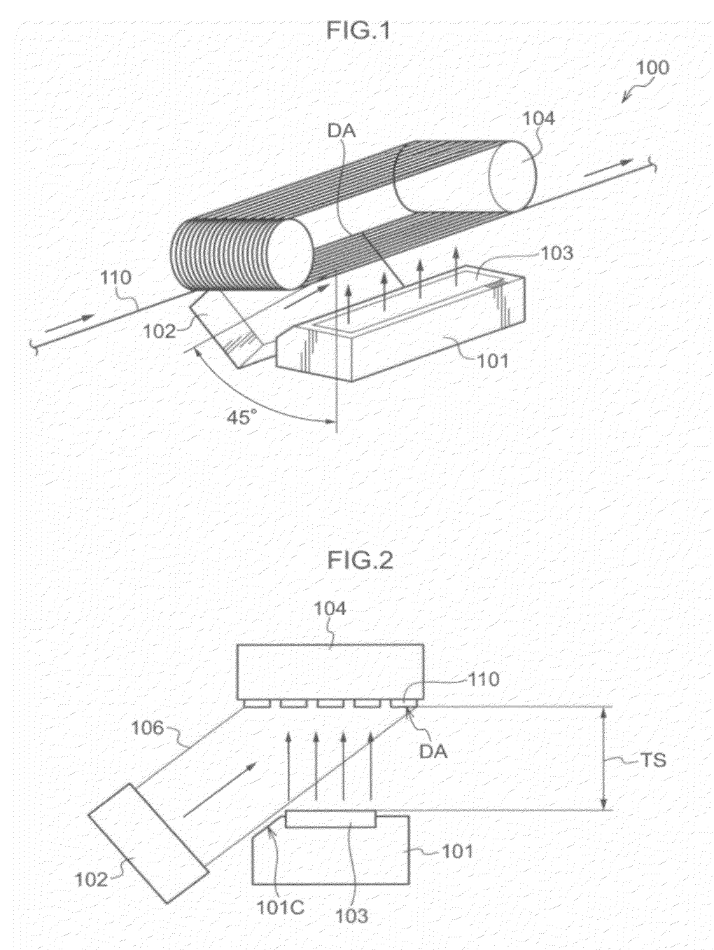

FIG. 1 shows a skeleton framework of a sputtering apparatus used for sputtering by the IBAD method. FIG. 2 shows a skeleton framework of the sputtering apparatus shown in FIG. 1, as viewed from a substrate-conveying direction.

As shown in FIGS. 1 and 2, a sputtering apparatus 100 has a configuration including a sputter gun 101 having a target (a deposition source) 103 inside, an assisting ion source 102, and a substrate-conveying section 104. The sputtering apparatus 100 is housed in a vacuum container (not shown), the inside of which is adapted to be filled with a predetermined atmospheric gas and deposition particles can be deposited on a deposition area DA in the atmospheric gas. The sputtering apparatus 100 also includes a heater for applying heat, which is not shown in the drawings, whereby the deposition area DA can be heated to an intended temperature.

A substrate 110 is conveyed into the sputtering apparatus 100 by the substrate-conveying section 104, and a surface of the substrate 110 acts as the deposition area DA.

The sputter gun 101 is an apparatus in which the target (deposition source) 103 is provided inside and inert gas ions (such as Ar⁺) are generated by RF (Radio Frequency) plasma or DC (direct current) plasma so as to sputter deposition particles from the target 103 by collision of the ions. Additionally, the assisting ion source 102 has an ion gun that accelerates and releases ions generated by an ion generator, whereby an intended assisting ion beam 106 can be applied onto the deposition area DA.

The deposition particles sputtered from the target 103 as described above are deposited on the deposition area DA of the substrate 110 opposing the target 103 to form an oxide thin film. At this time, the assisting ion beam 106 is irradiated by the assisting ion source 102 from an oblique direction to the deposition area of the substrate 110. The assisting ion beam 106 applied from the oblique direction has a property of sputtering deposition particles facing directions other than a specific direction, thereby forming an oxide thin film in which a- and b-axes of the deposition particles (crystal) are oriented, on the deposition area DA of the substrate 110.

In this case, in the oxide thin film production method according to the present invention, by controlling such that the sputter energy density is in the above-mentioned range, an oxide thin film having high biaxial orientation is formed.

Additionally, by controlling such that the distance TS between the target (deposition source) 103 and the deposition area DA is in the above-mentioned range, an oxide thin film having high biaxial orientation is formed.

Furthermore, by controlling such that the pressure of the atmospheric gas is in the above-mentioned range, an oxide thin film having high biaxial orientation is formed.

Particularly, from the viewpoint of setting the distance TS between the target (deposition source) 103 and the deposition area DA within the above range, a cover of the sputter gun 101 (the deposition source cover enclosing the target (deposition source) 103) is preferably formed so as to have a shape that does not intersect a region through which the ion beam 106 to be irradiated to the deposition area DA travels, as shown in FIGS. 1 and 2. It is also preferable to obliquely cut off a portion of the cover (a portion indicated by 101C in FIG. 2) overlapping the region along which the ion beam 106 travels.

Other conditions for deposition of an oxide thin film (such as a biaxially oriented layer as the intermediate layer) may be appropriately set in accordance with a film thickness and the like. For example, the following ranges are preferable as the other conditions:
Assisting ion beam voltage in IBAD: from 800 V to 1500 V
Assisting ion beam electric current in IBAD: from 80 mA to 350 mA
Assisting ion beam accelerating voltage in IBAD: approximately 200 V
Sputtering output: from 800 W to 1700 W
Substrate-conveying speed: from 80 m/h to 500 m/h
Deposition temperature: from 5° C. to 250° C.

An oblique angle of the ion beam 106 irradiated to the deposition area DA is preferably from 10° to 80° with respect to a normal line direction of the deposition area, more preferably from 40° to 50°, and particularly preferably approximately 45°.

An oxide thin film can be formed as described above using a sputtering apparatus 100 shown in FIGS. 1 and 2. Examples of the oxide thin film produced by the present embodiment include an MgO thin film (Mg is used as the target 103 and O₂ is used as the atmospheric gas inside the sputtering apparatus) and an NbO thin film (Nb is used as the target 103 and O₂ is used as the atmospheric gas inside the sputtering apparatus).

As for the ions released from the ion gun of the assisting ion source 102, argon ions or oxygen ions are used.

(Substrate for Superconducting Wire Rod and Superconducting Wire Rod)

Next, a description is provided with respect to a substrate for a superconducting wire rod and a superconducting wire rod as usage examples of the oxide thin film formed by the above-described oxide thin film production method according to the present invention. The oxide thin film formed by the oxide thin film production method according to the invention is favorably used as an intermediate layer in a substrate for a superconducting wire rod and a superconducting wire rod.

Hereinafter, one example of the oxide thin film used as the intermediate layer will be described in detail with reference to the attached drawings. In the drawings, the same components (constituent elements) or components having corresponding function will be given the same reference numerals and explanation of the components will be omitted unless it is necessary.

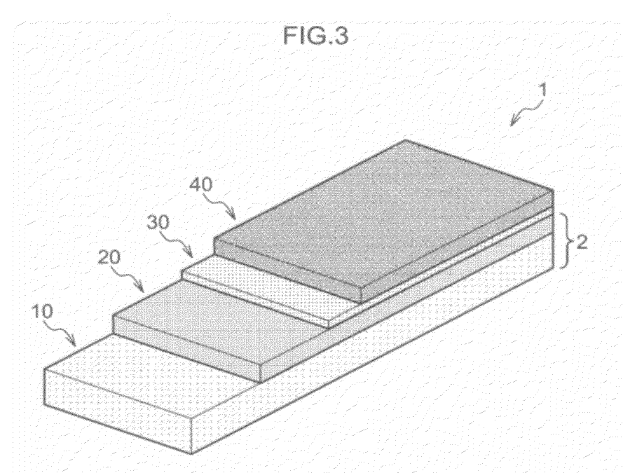

FIG. 3 shows a laminate structure of the superconducting wire rod described above.

As shown in FIG. 3, a superconducting wire rod 1 has a lamination structure in which, in the following order, an intermediate layer 20, a superconducting layer 30, and a protecting layer 40 are sequentially formed on a tape-shaped metallic substrate 10.

Substrate

The metallic substrate 10 is a low-magnetic non-oriented metallic base material. Regarding the shape of the metallic substrate 10, variously-shaped materials, such as lumber, wire rod, or streak material may be used as well as the above-described tape-shaped material. As for the material of the metallic substrate 10, for example, a metal exhibiting excellent strength and thermal resistance, such as Cu, Ni, Ti, Mo, Nb, Ta, W, Mn, Fe, or Ag; or alloys thereof may be used. Particularly preferred are metals that are excellent in terms of corrosion resistance and thermal resistance, such as stainless steel, Hastelloy®, or other nickel-based alloys. In addition, various ceramics may be arranged on these metallic materials.

Intermediate Layer

The intermediate layer 20 is a layer formed on the metallic substrate 10 to achieve high in-plane orientation in the superconducting layer 30. Physical characteristic values such as coefficient of thermal expansion and lattice constant indicate intermediate values between the metallic substrate 10 and an oxide superconductor that is a component of the superconducting layer 30.

Examples of the intermediate layer 20 include a bed layer (B-1), a biaxially oriented layer (B-2), and a cap layer (B-3). Herein, a description of an embodiment will be provided with reference to the drawing, in which, sequentially from a surface of the metallic substrate 10, the bed layer (B-1), the biaxially oriented layer (B-2), and the cap layer (B-3) are formed as the intermediate layer 20 on the substrate, although the invention is not limited to the embodiment.

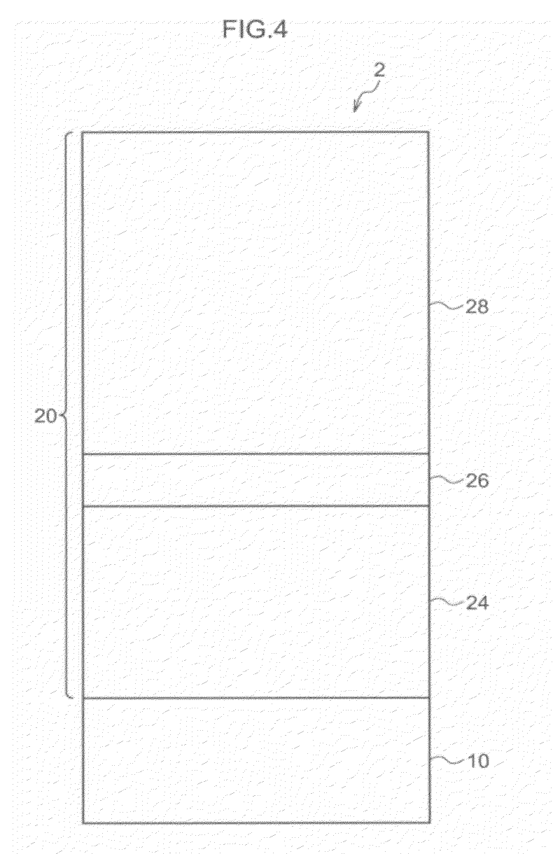

FIG. 4 is a cross-sectional detail view showing the metallic substrate 10 and the intermediate layer 20 included in the laminate structure of the superconducting wire rod 1 shown in FIG. 3.

As shown in FIG. 4, the intermediate layer 20 of the superconducting wire rod 1 is configured with the bed layer 24, the biaxially oriented layer 26, and the cap layer 28.

Bed Layer (B-1)

The bed layer 24 is formed on the surface of the substrate 10.

As a constitutional material for the bed layer 24, for example, Gd₂Zr₂O_{7-δ} (−1<δ<1, hereinafter referred to as GZO), YAlO₃ (yttrium aluminate), YSZ (yttria-stabilized zirconia), Y₂O₃, Gd₂O₃, Al₂O₃, B₂O₃, Sc₂O₃, Cr₂O₃, REZrO, and RE₂O₃ can be used. Among them, GZO, Y₂O₃, or YSZ is preferred. Herein, RE represents a single or plurality of rare-earth elements. Examples of the rare-earth elements include Y, Nd, Sm, Eu, Gd, Dy, Ho, Er, Tm, Yb, and Lu. The bed layer 24 may have, for example, a function of improving biaxial orientation. To obtain the biaxial orientation improving function, GZO is preferably used as the constitutional material of the bed layer 24.

The film thickness of the bed layer 24 is not specifically limited, but, for example, it is from 10 nm to 200 nm.

The method for forming (depositing) the bed layer 24 is, for example, a deposition method in accordance with a RF sputtering method in an argon atmosphere.

In the RF sputtering method, inert gas ions (such as Ar⁺) generated by plasma discharge are collided with a deposition source (such as GZO) to sputter deposition particles, which in turn deposit on a deposition area to form a film. In this case, conditions for deposition are appropriately set according to the constitutional material, film thickness and the like of the bed layer 24. For example, RF sputtering output is set within the range of from 100 W to 500 W; substrate-conveying speed is set within the range of from 10 m/h to 100 m/h; and deposition temperature is set within the range of from 20° C. to 500° C.

For deposition of the bed layer 24, an ion-beam sputtering method can also be used in which ions generated by an ion generator (ion gun) are collided with a deposition source. Alternatively, the bed layer 24 can be of multilayer structure, such as a combination of an Y₂O₃ layer and an Al₂O₃ layer.

Biaxially Oriented Layer (B-2)

In the present embodiment, as a biaxially oriented layer 26, the oxide thin film formed by the above-described oxide thin film production method according to the present invention may be used.

The biaxially oriented layer 26 is formed on the bed layer 24, and the biaxially oriented layer 26 is a layer to orient crystals in the superconducting layer 30 in a specific direction.

Examples of a constitutional material for the biaxially oriented layer 26 include polycrystalline materials such as MgO, CeO₂, YSZ, and NbO. Alternatively, the same material as that of the bed layer 24, such as GZO, may be used.

The film thickness of the biaxially oriented layer 26 is not specifically limited, but it is, for example, from 1 nm to 20 nm.

Cap Layer (B-3)

The cap layer 28 is formed on the biaxially oriented layer 26 and the cap layer 28 is a layer to protect the biaxially oriented layer 26 and also to improve lattice consistency with the superconducting layer 30.

Examples of a material for the cap layer 28 include MgO, CeO₂, YSZ, LaMnO₃ (LMO), and SrTiO₃ (STO).

The film thickness of the cap layer 28 is not specifically limited. To obtain sufficient orientation, the film thickness thereof is preferably 50 nm or more, and more preferably 300 nm or more.

An example of the method for forming (depositing) the cap layer 28 includes a deposition by a PLD method or a sputtering method. Conditions for the deposition by the RF sputtering method may be appropriately set in accordance with a constitutional material, a film thickness and the like of the cap layer 28. For example, the following conditions are preferable:
RF sputtering output: from W 400 to 1000 W
Substrate-conveying speed: from 5 m/h to 80 m/h
Deposition temperature: from 450° C. to 800° C.

Superconducting Layer

Next, a description of the superconducting wire rod will be provided. The superconducting layer 30 is formed on a substrate for the superconducting wire rod.

The superconducting layer 30 is formed on the intermediate layer 20 and composed of an oxide superconductor, particularly a copper oxide superconductor. The copper oxide superconductor can be made of a crystalline material represented by a composition formula, such as REBa₂Cu₃O_{7-δ} (referred to as RE-123).

RE in the REBa₂Cu₃O_{7-δ} mentioned above represents a single or plurality of rare-earth elements, such as Y, Nd, Sm, Eu, Gd, Dy, Ho, Er, Tm, Yb, or Lu, among which Y is often used. In addition, the symbol δ represents an oxygen nonstoichiometric amount, which is, for example, from 0 to 1. From a viewpoint of obtaining a high superconducting transition temperature, the nearer to 0, the better the value of δ is.

The film thickness of the superconducting layer 30 is not specifically limited, but for example, it is from 0.8 μm to 10 μm.

Examples of the method for forming (depositing) the superconducting layer 30 include a TFA-MOD method, a PLD method, a CVD method, a MOCVD method, and a sputtering method. Among these deposition methods, the MOCVD method is preferably used, from the viewpoints of no requirement of high vacuum, easiness of increase in area and excellent mass productivity. Conditions for deposition by the MOCVD method are appropriately set in accordance with a constitutional material, a film thickness and the like of the superconducting layer 30. For example, the following conditions are preferable:
Substrate-conveying speed: from 80 m/h to 500 m/h
Deposition temperature: from 800 to 900° C. (the case of YBa₂Cu₃O_{7-δ})

Additionally, in the time of deposition of REBa₂Cu₃O_{7-δ} or (La₁₋ₓBaₓ)₂CuO_{4-δ}, the deposition is preferably carried out in an oxygen gas atmosphere from the viewpoint of reducing the oxygen nonstoichiometric amount 8 to improve superconductive characteristics.

On an upper surface of the superconducting layer 30 thus formed, the protecting layer 40 an example of which is made of silver by sputtering, is deposited. In addition, after production of the superconducting wire rod 1 by deposition of the protecting layer 40, the superconducting wire rod 1 may be subjected to a heat treatment.

In the present embodiment, preferable structures of the intermediate layer can be exemplified as follows. In each example of the intermediate layer, in the following order, a bed layer (such as GZO), a biaxially oriented layer (IBAD-MgO), and a cap layer (such as
CeO₂/Epi-MgO) are disposed on a substrate (Hastelloy).
CeO₂/IBAD-MgO/GZO/Hastelloy
CeO₂/Epi-MgO/IBAD-MgO/GZO/Hastelloy
CeO₂/LMO/IBAD-MgO/GZO/Hastelloy
CeO₂/LMO/Epi-MgO/IBAD-MgO/GZO/Hastelloy
LMO/Epi-MgO/IBAD-MgO/GZO/Hastelloy
STO/Epi-MgO/IBAD-MgO/GZO/Hastelloy
Epi-MgO/IBAD-MgO/GZO/Hastelloy
LMO/IBAD-MgO/GZO/Hastelloy
STO/IBAD-MgO/GZO/Hastelloy
CeO₂/IBAD-MgO/Y₂O₃/Hastelloy
CeO₂/Epi-MgO/IBAD-MgO/Y₂O₃/Hastelloy
CeO₂/LMO/IBAD-MgO/Y₂O₃/Hastelloy
CeO₂/LMO/Epi-MgO/IBAD-MgO/Y₂O₃/Hastelloy
LMO/Epi-MgO/IBAD-MgO/Y₂O₃/Hastelloy
STO/Epi-MgO/IBAD-MgO/Y₂O₃/Hastelloy
Epi-MgO/IBAD-MgO/Y₂O₃/Hastelloy
LMO/IBAD-MgO/Y₂O₃/Hastelloy
STO/IBAD-MgO/Y₂O₃/Hastelloy

In addition, GZO, LMO, and STO above are abbreviations for Gd—Zr—O (Gd₂Zr₂O₇₋ₓ, −1<x<1), La—Mn—O (LaMnO₃, −1<x<1), and Sr—Ti—O (SrTiO₃, −1<x<1), respectively. Furthermore, IBAD-MgO is an MgO layer deposited by the IBAD method, and Epi-MgO is a self-oriented MgO layer epitaxially grown on the IBAD-MgO layer by the PLD method or the like.

(Modifications)

Although the specific embodiments have been described in detail above, the present invention is not limited thereto. It will be obvious to those skilled in the art that other various embodiments are possible without departing from the scope of the invention. For example, the above-described plurality of embodiments may be appropriately combined together to implement the invention. Alternatively, the following modifications may be combined together as appropriate.

For example, the bed layer 24 or the protective layer 40 can be omitted. In the above, a case in which the metallic substrate 10 is made of a metal is described. Alternatively, the substrate 10 may be formed of a resin or the like having a high heat-resistance.

Between the biaxially oriented layer 26 and the cap layer 28, a lattice matching layer including at least one selected from LMO and STO may be provided in order to improve the lattice matching of the cap layer 28.

In the above, a description of the case where the oxygen nonstoichiometric amount δ of the above material, such as YBa₂Cu₃O_{7-δ}, is 0 or larger (the case of a positive value) has been provided. However, the value may be negative.

According to the present invention, for example, the following aspects are provided.

(1) A method for producing an oxide thin film, including depositing sputtered particles from a metallic deposition source on a deposition area under the condition of a sputtering energy density of 9.5 W/cm² to 20 W/cm² according to a magnetron sputtering method to form the oxide thin film, while irradiating an ion beam from an oblique direction with respect to the deposition area.

(2) The method for producing an oxide thin film according to (1), wherein a pressure of an atmospheric gas for sputtering according to the magnetron sputtering method is from 50 mPa to 700 mPa.

(3) The method for producing an oxide thin film according to (1) or (2), wherein a distance between the deposition source and the deposition area is set within the range of from 80 mm to 100 mm.

(4) The method for producing an oxide thin film according to (2), including providing a deposition source cover for enclosing the deposition source, the deposition source cover having a shape that does not intersect a region through which the ion beam irradiated to the deposition area travels.

(5) The method for producing an oxide thin film according to any one of (1) to (4), wherein a voltage of the ion beam (an assisting ion beam) irradiated from an oblique direction with respect to the deposition area is set within the range of from 800 V to 1500 V.

(6) The method for producing an oxide thin film according to any one of (1) to (5), wherein an electric current of the ion beam (an assisting ion beam) irradiated from an oblique direction with respect to the deposition area is set within the range of from 80 mA to 350 mA.

(7) The method for producing an oxide thin film according to any one of (1) to (6), wherein an acceleration voltage of the ion beam is set to about 200 V.

(8) The method for producing an oxide thin film according to any one of (1) to (7), wherein an output of the sputtering is set within the range of from 800 W to 1700 W.

According to the present invention, in the production of an oxide thin film according to a magnetron sputtering method, there can be provided an oxide thin film production method whereby a film having high biaxial orientation can be formed.

All publications, patent applications, and technical standards mentioned in this specification are herein incorporated by reference to the same extent as if each individual document, patent application, or technical standard was specifically and individually indicated to be incorporated by reference.

### Examples

Hereinafter, Examples will be described, but the present invention is not limited to the following Examples.

(Metallic Substrate)

First, as a metallic substrate, there was prepared an Ni-base alloy substrate (Hastelloy®: Ni-16Cr-15.6Mo-6Fe-4W-2Co) rolled and processed into a tape shape having a width of 10 mm, a thickness of 100 μm, and a length of 200 m. To improve characteristics properly required for an orientation substrate used for a superconducting wire rod, a surface of the metallic substrate was polished so as to have Ra value of 10 nm or less.

(Bed Layer (GZO Layer))

Next, a Gd₂Zr₂O₇ (GZO) layer (film thickness: 110 nm) was deposited on the metallic substrate by the ion-beam sputtering method at room temperature.

(Biaxially Oriented Layer (IBAD-MgO Layer))

An MgO layer was formed on the bed layer (GZO layer) by the IBAD method using the RF sputtering apparatus shown in FIGS. 1 and 2 under the following conditions:
Target: Mg
Atmospheric gas: Ar+O₂
Distance between deposition source and deposition area: 90 mm
Atmospheric pressure of an Ar+O₂ mixture gas: 140 mPa
RF sputtering power: from 1200 W to 1700 W (values shown in Table 1 below)
Sputtering energy density: from 11.6 W/cm² to 16.5 W/cm² (Values shown in Table 1 below)
Ions released from assisting ion beam in IBAD: Ar⁺
Voltage of assisting ion beam in IBAD: from 800 V to 1500 V
Electric current of assisting ion beam in IBAD: from 80 mA to 350 mA
Acceleration voltage of assisting ion beam in IBAD: 200V
Angle of assisting ion beam in IBAD applied onto deposition area DA: 45°
Production speed (substrate-conveying speed): from 80 m/h to 500 m/h
Deposition temperature: 200° C.
Deposition rate: 1 A/s
Film thickness: 3.0 nm to 10 nm

(Cap Layer (CeO₂ Layer))

On the biaxially oriented layer (IBAD-MgO layer) was formed a CeO₂ layer by using the RF sputtering apparatus under the following conditions:
Target: CeO₂
Production speed (substrate-conveying speed): from 5 m/h to 80 m/h
Film thickness: from 200 nm to 500 nm

Regarding the obtained substrates for a superconducting wire rod, the degrees of in-plane orientation ΔΦ were evaluated by the following method.

The evaluation of the in-plane orientation ΔΦ was carried out by pole figure measurement to obtain a mean value of scan-peak half widths (ΔΦ). The results are shown in Table 1.

TABLE 1

| RF sputtering power | Sputtering energy density | ΔΦ |
|---|---|---|
| [W] | [W/cm²] | [degrees] |
| 1200 | 11.6 | 11.4 |
| 1250 | 12.1 | 7.3 |
| 1300 | 12.6 | 5.2 |
| 1350 | 13.1 | 3.9 |
| 1400 | 13.6 | 3.4 |
| 1450 | 14.0 | 3.3 |
| 1500 | 14.5 | 2.9 |
| 1600 | 15.5 | 4.1 |
| 1700 | 16.5 | 8.2 |

As shown in Table 1, in the above Examples in each of which the sputtering energy density satisfies the requirement of the present invention, excellent in-plane orientation ΔΦ is obtained.

What is claimed is:

1. A method for producing an oxide thin film, comprising depositing sputtered particles from a metallic deposition source on a deposition area under the condition of a sputtering energy density of 9.5 W/cm² to 20 W/cm² according to a magnetron sputtering method to form the oxide thin film, while irradiating an ion beam from an oblique direction with respect to the deposition area.

2. The method for producing an oxide thin film according to claim 1, wherein a pressure of an atmospheric gas for sputtering according to the magnetron sputtering method is set within the range of from 50 mPa to 700 mPa.

3. The method for producing an oxide thin film according to claim 1, wherein a distance between the deposition source and the deposition area is set within the range of from 80 mm to 100 mm.

4. The method for producing an oxide thin film according to claim 3, wherein a pressure of an atmospheric gas for sputtering according to the magnetron sputtering method is set within the range of from 50 mPa to 700 mPa.

5. The method for producing an oxide thin film according to claim 2, comprising further providing a deposition source cover for enclosing the deposition source, the deposition source cover having a shape that does not intersect a region through which the ion beam irradiated to the deposition area travels.

6. The method for producing an oxide thin film according to claim 1, wherein a voltage of the ion beam irradiated from an oblique direction with respect to the deposition area is set within the range of from 800 V to 1500 V.

7. The method for producing an oxide thin film according to claim 2, wherein a voltage of the ion beam irradiated from an oblique direction with respect to the deposition area is set within the range of from 800 V to 1500 V.

8. The method for producing an oxide thin film according to claim 1, wherein an electric current of the ion beam irradiated from an oblique direction with respect to the deposition area is set within the range of from 80 mA to 350 mA.

9. The method for producing an oxide thin film according to claim 2, wherein an electric current of the ion beam irradiated from an oblique direction with respect to the deposition area is set within the range of from 80 mA to 350 mA.

10. The method for producing an oxide thin film according to claim 1, wherein an acceleration voltage of the ion beam irradiated from an oblique direction with respect to the deposition area is set to about 200 V.

11. The method for producing an oxide thin film according to claim 2, wherein an acceleration voltage of the ion beam irradiated from an oblique direction with respect to the deposition area is set to about 200 V.

12. The method for producing an oxide thin film according to claim 1, wherein an output of the sputtering is set within the range of from 800 W to 1700 W.

13. The method for producing an oxide thin film according to claim 2, wherein an output of the sputtering is set within the range of from 800 W to 1700 W.
